(19) United States
(12) Patent Application Publication
(10) Pub. No.: US 2008/0254619 A1
(43) Pub. Date: Oct. 16, 2008

(54) METHOD OF FABRICATING A SEMICONDUCTOR DEVICE

(76) Inventors: Tsang-Jung Lin, Tao-Yuan Hsien (TW); Fong-Lung Chuang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/735,448

(22) Filed: Apr. 14, 2007

(51) Int. Cl. H01L 21/44

(52) U.S. Cl. 438/675

(57) ABSTRACT

A method of fabricating a semiconductor device is provided. First, a semiconductor substrate and a dielectric layer positioned on the semiconductor substrate are prepared. Subsequently, the dielectric layer is etched to form a hole structure in the dielectric layer. Afterward, a degas process is performed. An ultraviolet (UV) treatment is carried out to the semiconductor substrate in the degas process so as to expel at least a gas contained in the dielectric layer. Next, a barrier layer is formed on the sidewall and on the bottom of the hole structure. Furthermore, the hole structure is filled with a conductive material. Since the UV treatment can degas the dielectric layer efficiently, the formed semiconductor device can have a fine and stable structure.

### BACKGROUND OF THE INVENTION

1. Field of the Invention

The present invention relates to a method of fabricating a semiconductor device, and more particularly, to a method of fabricating a semiconductor device by utilizing a degas process.

2. Description of the Prior Art

For today's narrower line width and faster production speeds, damascene structures are formed in a dielectric material by means of a physical vapor deposition (PVD) metal process so as to fabricate metal interconnects of integrated circuits. Generally speaking, the PVD process utilizes inert gas, such as argon, to bombard a target material in high speed for sputtering atoms from the target. Thereafter, the sputtered atoms of the target material, such as aluminum, titanium, or alloy thereof, evenly deposit on the surface of a wafer. The reaction chamber provides a vacuum environment with high temperature, and thus the metal atoms deposited on the wafer become crystallized grains so as to form a metal layer. Afterward, lithography and etching processes are performed to pattern the metal layer so that desired metal interconnects or semiconductor devices are observed.

Please refer to FIGS. 1-5. FIGS. 1-5 are schematic diagrams of forming a conducting plug on a semiconductor wafer according to the prior art. As shown in FIG. 1, a semiconductor wafer 10 is provided first. The semiconductor wafer 10 includes a semiconductor substrate 12 and a dielectric layer 14 positioned on the semiconductor substrate 12. Subsequently, a patterning process is performed on the semiconductor wafer 10 so as to form a plug hole 16 in the dielectric layer 14.

Thereafter, as shown in FIG. 2, the semiconductor wafer 10 is transferred into a PVD equipment 40. The PVD equipment 40 mainly includes a buffer chamber 42 and a transfer chamber 44. The buffer chamber 42 has a robot arm 42a, and the transfer chamber 44 has a robot arm 44a so as to transfer the semiconductor wafer 10. A pass-through chamber 46 and a cool down chamber 48 are disposed between the buffer chamber 42 and transfer chamber 44 so that the semiconductor wafer 10 can pass by or cool down. The buffer chamber 42 is coupled to load-lock chambers 52 and degas chambers 54. The transfer chamber 44 is coupled to a cluster of reaction chambers 56, 58, 62, 64 where the reaction chambers 56, 58, 62, 64 are all PVD chambers.

The semiconductor wafer 10 is first loaded into the PVD equipment 40 through one of the load-lock chambers 52. Thereafter, the semiconductor wafer 10 is moved into one of the degas chambers 54 for undergoing a degas process, as shown in FIG. 3. The degas chamber 54 includes a carrier 66 and a halogen lamp (not shown in the figure) where the carrier 66 is usually made with metals having high heat conductivities. In the degas chamber 54, the semiconductor wafer 10 is placed on the surface of the carrier 66, and a halogen lamp treatment is performed so that the semiconductor wafer 10 is irradiated by the halogen lamp. Consequently, moisture in the semiconductor wafer 10 and parts of contaminations on the surface of the semiconductor wafer 10 are vaporized because of the radiation of the halogen lamp for pre-cleaning some gases and contaminations from a pre-layer process.

Next, the cleaned semiconductor wafer 10 is moved from the buffer chamber 42 into the transfer chamber 44. Thereafter, the robot arm 44a moves the semiconductor wafer 10 into the reaction chamber 56 for undergoing a barrier layer deposition process, and then into the reaction chamber 62 for undergoing a metal layer deposition process. As shown in FIG. 4, a barrier layer 18 is deposited on the surface of the semiconductor wafer 10 by means of the above-mentioned barrier layer deposition process. The barrier layer 18, made with titanium (Ti) or titanium nitride (TiN), covers the surface of the dielectric layer 14, the sidewall of the plug hole 16, and the bottom of the plug hole 16. In addition, a metal layer 22 is deposited on the surface of the semiconductor wafer 10 by means of the above-mentioned metal layer deposition process, filling the plug hole 16. Next, the semiconductor wafer 10 departs from the PVD equipment 40 through one of the load-lock chambers 52.

Following that, as shown in FIG. 5, excess portions of the metal layer 22 are removed from the semiconductor wafer 10 through a chemical mechanical polishing (CMP) process so as to make the metal layer 22 located in the plug hole 16 become a conducting plug 24. The chemical mechanical polishing process are well known in the art and thus not explicitly shown in the drawings.

Since the traditional dielectric layer 14 is usually low-k material having micro-holes, some gases, especially water vapor, are easily contained in the dielectric layer 14. Moreover, the etching gas, such as tetrafluoromethane (CF₄), is used to etch the dielectric layer 14 during fabrication of the plug hole 16. The etching gas often remains in the micro-holes of the dielectric layer 14 too. The traditional degas process is performed by means of the halogen lamp treatment in the prior art. However, the halogen lamp treatment is not a forceful degas process, so it does not degas the dielectric layer 14 effectively. It is important to remove the water vapor and other gases contained in the dielectric layer 14 before depositing the barrier layer 18 and the metal layer 22. Otherwise, the water vapor and other gases contained in the dielectric layer 14 will cause the serious outgassing pollution during the deposition processes, and change the thickness of the dielectric layer 14 and the size of the plug hole 16. As a result, the deposited barrier layer 18 and the deposited metal layer 22 have high specific resistances. In addition to the deformation of the dielectric layer 14, a bad degas process prevents the barrier layer 18 from being deposited effectively on the dielectric layer 14. In this situation, the subsequently formed metal layer 22 effuses out through the barrier layer 18 to form the defect of extrusion effect.

### SUMMARY OF THE INVENTION

It is therefore a primary objective of the present invention to provide a method of fabricating a semiconductor device to solve the above-mentioned problems.

According to the present invention, a method of fabricating a semiconductor device is disclosed. First, a semiconductor substrate and a dielectric layer positioned on the semiconductor substrate are provided. Subsequently, the dielectric layer is etched to form at least a hole structure therein. Next, a degas process is performed on the semiconductor substrate. The degas process makes at least a gas escape from the dielectric layer by an ultraviolet treatment. Furthermore, a barrier layer is formed on a sidewall and on a bottom of the hole structure. Thereafter, the hole structure is filled with a conductive material.

From one aspect of the present invention, a method of fabricating a semiconductor device is disclosed. First, an etching process is performed on a semiconductor substrate. Subsequently, a degas chamber is provided. The degas chamber has a carrier and an ultraviolet lamp. Next, the semiconductor substrate is transferred into the degas chamber, wherein an ultraviolet treatment is performed by the ultraviolet lamp so as to make a gas escape from the semiconductor substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-5 are schematic diagrams of forming a conducting plug on a semiconductor wafer according to the prior art

FIGS. 6 through 10 are schematic diagrams illustrating a method of manufacturing a conducting plug in accordance with a first preferred embodiment of the present invention.

FIGS. 11 through 13 are schematic diagrams illustrating degas processes in accordance with a second, a third and a fourth preferred embodiment of the present invention respectively.

FIG. 14 is a schematic diagram illustrating a method of manufacturing a dual damascene structure in accordance with a fifth preferred embodiment of the present invention.

FIG. 15 is a schematic diagram illustrating a method of manufacturing a shallow trench isolation structure in accordance with a sixth preferred embodiment of the present invention.

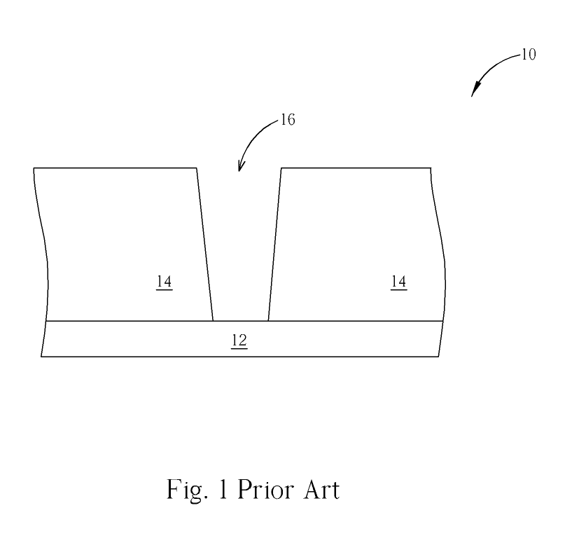

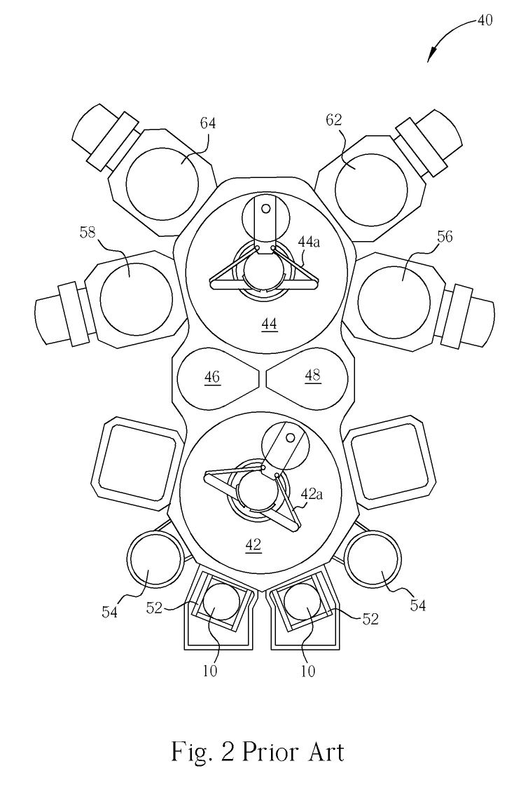

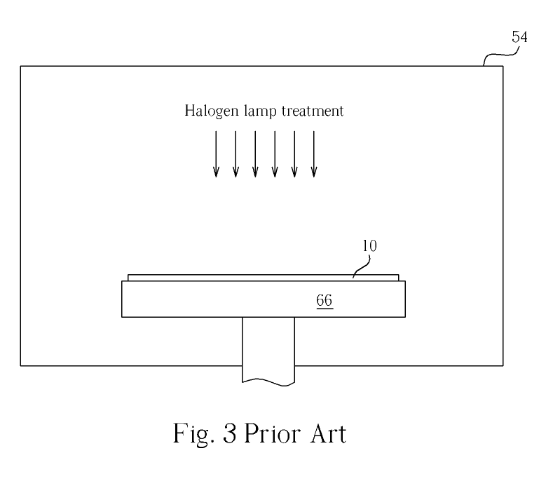

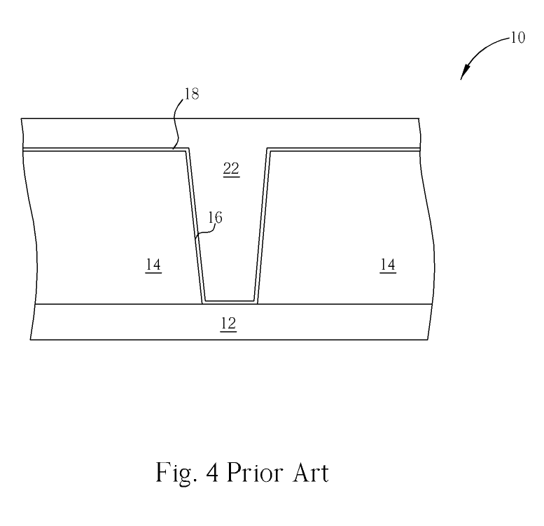

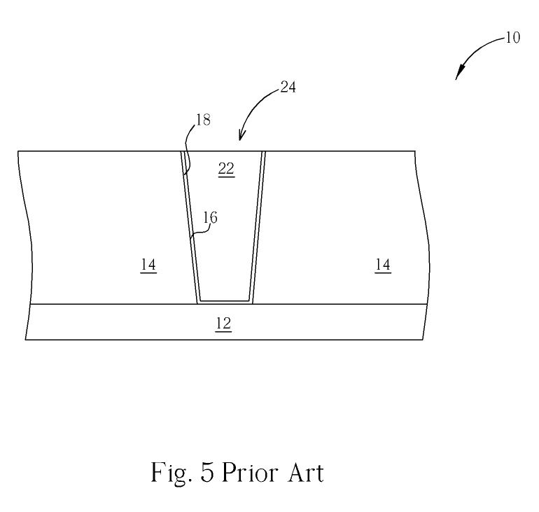

### DETAILED DESCRIPTION

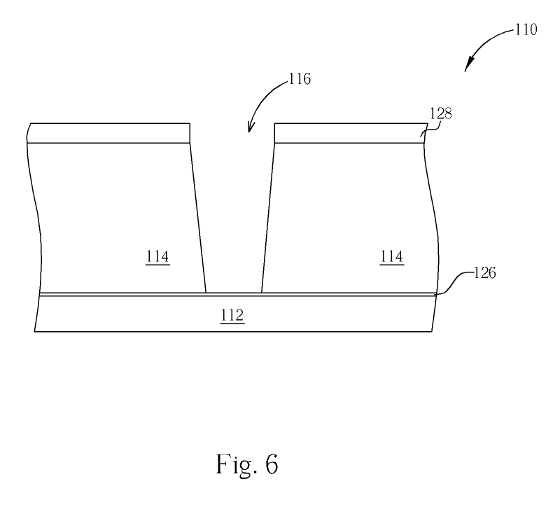

Please refer to FIGS. 6 through 10. FIGS. 6 through 10 are schematic diagrams illustrating a method of manufacturing a conducting plug in accordance with a first preferred embodiment of the present invention, where like number numerals designate similar or the same parts, regions or elements. The formed conducting plug in this preferred embodiment can be a contact plug or a via plug. It is to be understood that the drawings are not drawn to scale and are only for illustration purposes. In addition, some lithographic and etching processes relating to the present invention method are known in the art and thus not explicitly shown in the drawings.

As shown in FIG. 6, a semiconductor wafer 110 is provided first. The semiconductor wafer 110 includes a semiconductor substrate 112, an etching stop layer 126 covering the semiconductor substrate 112, a dielectric layer 114 positioned on the etching stop layer 126, and a patterned hard mask 128 positioned on the dielectric layer 114. Subsequently, an etching process is performed on the dielectric layer 114 by utilizing the patterned hard mask 128 as an etching mask until the etching stop layer 126 is exposed so as to form a hole structure 116 in the dielectric layer 114.

It should be understood by a person skilled in this art that the etching stop layer 126 could be omitted in this preferred embodiment. In other words, it is not necessary that the above-mentioned etching process stops when exposing the etching stop layer 126. The above-mentioned etching process can stop at any moment so as to obtain a desired depth of the hole structure 116. The semiconductor substrate 112 may be any semiconductor substrate, such as a silicon substrate or a silicon-on-insulator (SOI) substrate. The etching stop layer 126 and the patterned hard mask 128 can be made out of any materials that have a high etching selectivity to the dielectric layer 114, such as a carbon silicon compound. The dielectric layer 114 can contain any materials having high dielectric constant, such as fluorinated silicate glass (FSG), undoped silicate glass (USG), phosphosilicate glass (PSG) or borophosposilicate glass (BPSG).

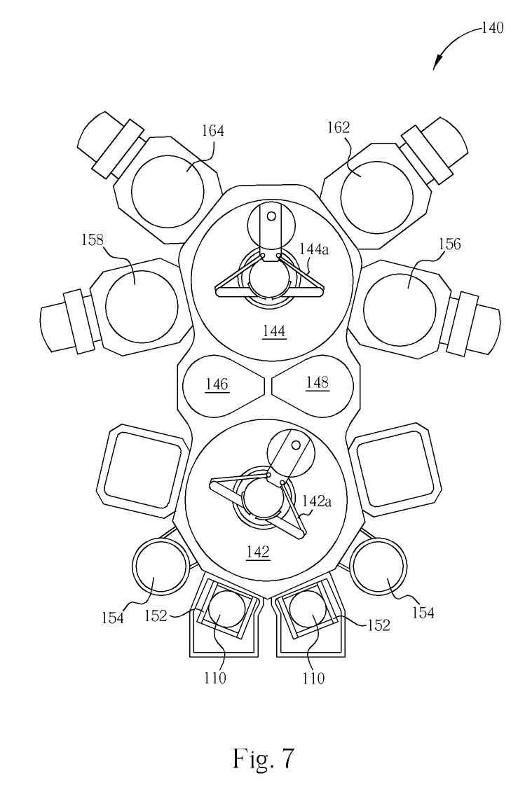

Thereafter, as shown in FIG. 7, the semiconductor wafer 110 is transferred into a PVD equipment 140, such as a multi-chamber PVD equipment. The PVD equipment 140 mainly includes a buffer chamber 142 and a transfer chamber 144. The buffer chamber 142 has a robot arm 142a, and the transfer chamber 144 has a robot arm 144a so as to transfer the semiconductor wafer 110. A pass-through chamber 146 and a cool down chamber 148 are disposed between the buffer chamber 142 and transfer chamber 144. The pass-through chamber 146 is prepared for the semiconductor wafer 110 to pass by, and the cool down chamber 148 is applied to cool the semiconductor wafer 110. The buffer chamber 142 is coupled to load-lock chambers 152 and degas chambers 154. The load-lock chambers 152 are utilized for loading current wafers, or unloading the processed wafers, and the degas chambers 154 are set for wafer degas processes. The transfer chamber 144 is coupled to a cluster of reaction chambers 156, 158, 162, 164 where the reaction chambers 156, 158, 162, 164 are all PVD chambers, such as a titanium deposition chamber, a titanium nitride deposition chamber, or a copper deposition chamber.

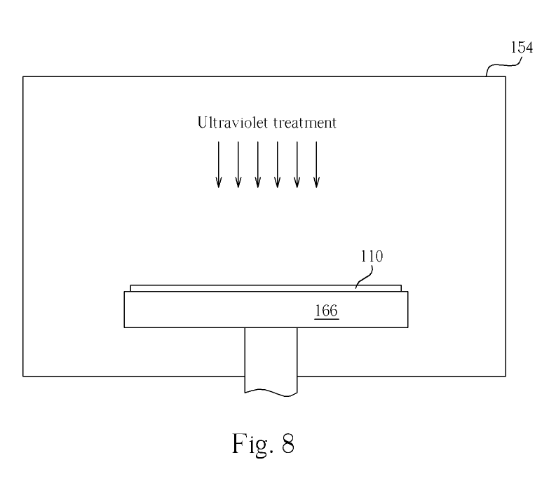

The semiconductor wafer 110 is first loaded into the PVD equipment 140 through one of the load-lock chambers 152. Thereafter, the semiconductor wafer 110 is moved into one of the degas chambers 154 for undergoing a degas process so that parts of contaminations on the surface of the semiconductor wafer 110 and gases in the semiconductor wafer 110, such as water vapor in the dielectric layer 114, are removed. As shown in FIG. 8, the degas chamber 154 includes a carrier 166 and an ultraviolet lamp (not shown in the figure). Generally speaking, the carrier 166 is usually made with metals having high heat conductivities, and is employed for placing the semiconductor wafer 110. In the degas chamber 154, the semiconductor wafer 110 is placed on the surface of the carrier 166, and an ultraviolet lamp treatment is performed so that the semiconductor wafer 110 is irradiated by the ultraviolet lamp. Consequently, moisture in the semiconductor wafer 110 and parts of contaminations on the surface of the semiconductor wafer 110 are vaporized because of the radiation of the ultraviolet lamp.

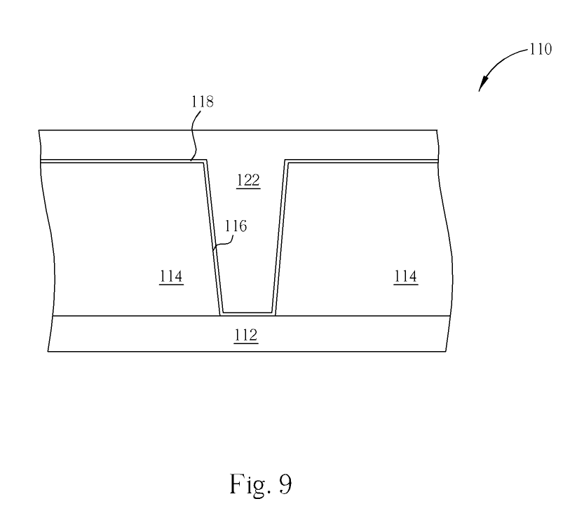

Next, the cleaned semiconductor wafer 110 is moved from the buffer chamber 142 into the transfer chamber 144. Thereafter, the robot arm 144a moves the semiconductor wafer 110 into the reaction chamber 156 for undergoing a barrier layer sputtering deposition process. Afterward, the semiconductor wafer 110 is immediately transferred into the cool down chamber 148. Once the semiconductor wafer 110 is loaded into the platform of the cool down chamber 148, a flow of inert gas (cooling gas) such as argon, helium or nitrogen is flowed into the chamber 18 to cool down the wafer. Thereafter, the semiconductor wafer 110 is transferred into the reaction chamber 162 for undergoing a metal layer sputtering deposition process. As shown in FIG. 9, a barrier layer 118 is deposited on the surface of the semiconductor wafer 110 by means of the above-mentioned barrier layer sputtering deposition process. The barrier layer 118 covers the surface of the dielectric layer 114, the sidewall of the hole structure 116, and the bottom of the hole structure 116 for preventing the metal ion diffusion of the following-formed metal layer. Accordingly, the barrier layer 118 can contain various combinations of tantalum (Ta), tantalum (TaN), titanium or titanium nitride. In addition, a metal layer 122 is deposited on the surface of the barrier layer 118 by means of the above-mentioned metal layer sputtering deposition process, filling the hole structure 116. It should be understood by a person skilled in this art that the metal layer 122 can include any conducting material having a high conductivity, such as copper, aluminum, tungsten or alloys of the above-mentioned metals. After the metal layer 122 is formed, the semiconductor wafer 110 departs from the PVD equipment 140 through one of the load-lock chambers 152. It should be noted that the said deposition processes can also be performed by means of evaporating.

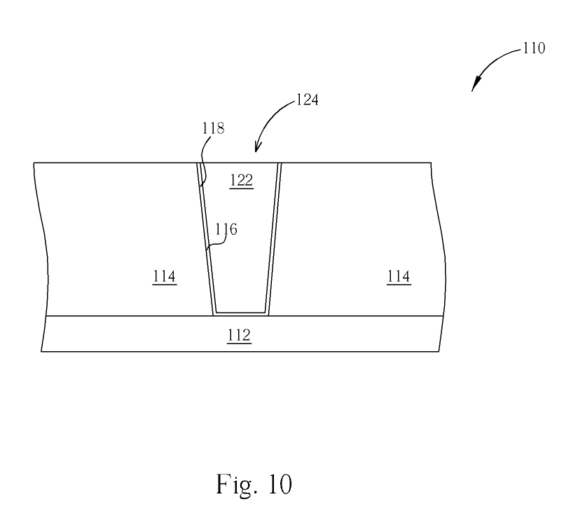

Following that, as shown in FIG. 10, excess portions of the metal layer 122 are removed from the semiconductor wafer 110 through a chemical mechanical polishing process or an etching back process so as to make the metal layer 122 located in the hole structure 116 become a conducting plug 124. In this preferred embodiment, the sputtering deposition process of forming the barrier layer 118 is carried out in the reaction chamber 156, and the sputtering deposition process of forming the metal layer 122 is carried out in the reaction chamber 162. However, the present invention should not be limited to those chambers. The main characteristic of the present invention is that the degas process is preformed by utilizing the ultraviolet treatment. Accordingly, the contained gases in the dielectric material can be removed effectively, and the following-formed material layer can cover the dielectric material closely.

Obviously, many variations are possible and the figures described herein are by way of example and not limitation. Thus, any process or method that includes an ultraviolet treatment in a degas process before depositing a material layer should fit the spirit of the present invention. For example, any ultraviolet-radiating device, such as the ultraviolet lamp, can be positioned in the buffer chamber 142, the load-lock chamber 152, the transfer chamber 144 or the reaction chamber 156 so that the semiconductor wafer 110 can undergo an ultraviolet treatment first before depositing the following material layer in the reaction chamber 156.

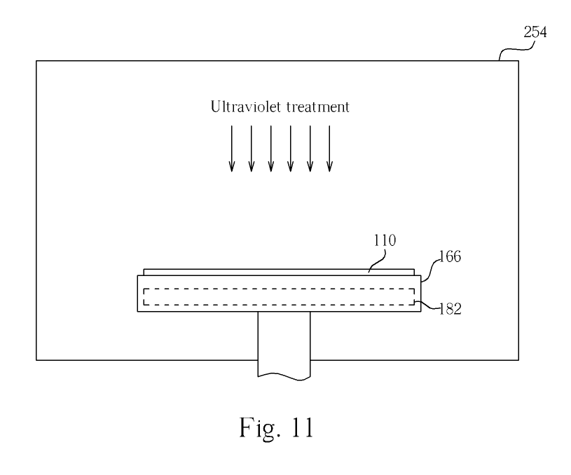

Furthermore, it should be understood by a person skilled in this art that the PVD equipment 140 shown in FIG. 7, and the degas chamber 154 shown in FIG. 8 are only one embodiment of the present invention. The present invention should not be limited to the multi-chamber PVD equipment. In other words, the present invention can also be performed in other kinds of PVD equipments or degas chambers. Please refer to FIGS. 11 through 13. FIGS. 11 through 13 are schematic diagrams illustrating degas processes in accordance with a second, a third and a fourth preferred embodiment of the present invention respectively, where like number numerals designate similar or the same parts, regions or elements.

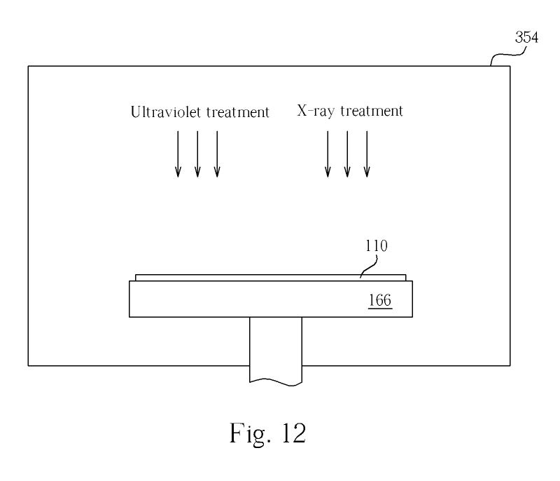

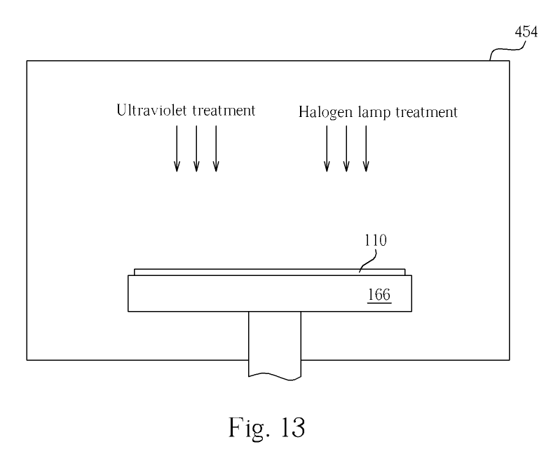

As shown in FIG. 11, in the second preferred embodiment, a heating device 182 can be further included in the degas chamber 254 or in the carrier 166 of the degas chamber 254 so as to heat the semiconductor wafer 110 uniformly during the ultraviolet treatment until the semiconductor wafer 110 has a required temperature. In other embodiments of the present invention, the heating device 182 can heat the semiconductor wafer 110 before or after the ultraviolet treatment. As shown in FIG. 12, in the third preferred embodiment, an X-ray device (not shown in the figure) can be further included in the degas chamber 354 so as to perform an X-ray treatment on the semiconductor wafer 110. The X-ray treatment can be carried out during the ultraviolet treatment. Otherwise, the X-ray device can irradiate the semiconductor wafer 110 before or after the ultraviolet treatment. As shown in FIG. 13, in the fourth preferred embodiment, a halogen lamp (not shown in the figure) can be further included in the degas chamber 454 so as to perform a halogen lamp treatment on the semiconductor wafer 110. The halogen lamp treatment can be carried out at the meanwhile with the ultraviolet treatment. Otherwise, the halogen lamp can irradiate the semiconductor wafer 110 before or after the ultraviolet treatment.

It should be noted that although the above-mentioned ultraviolet treatment is performed in-situ in the reaction chamber 154 of the PVD equipment 140, the ultraviolet treatment can be performed ex-situ in other embodiments. For instance, the semiconductor wafer 110 can undergo a degas process, such as a heating treatment, an X-ray treatment or a halogen lamp treatment, in a degas chamber first, and then undergo an ultraviolet treatment in another degas chamber. Otherwise, the semiconductor wafer 110 can undergo an ultraviolet treatment in a degas chamber first, and then undergo other degas processes as required.

On the other hand, although the said embodiments take the manufacturing process of forming a conducting plug as an example, it should be understood that the present invention can applied to the manufacturing process of forming other structures where a degas process is required. For instance, the present invention can be applied to the manufacturing process of forming a dual damascene structure, other single damascene structure or a shallow trench isolation (STI) structure.

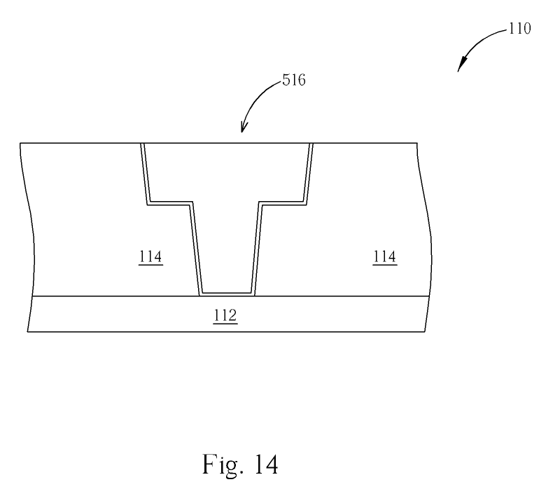

Please refer to FIG. 14. FIG. 14 is a schematic diagram illustrating a method of manufacturing a dual damascene structure in accordance with a fifth preferred embodiment of the present invention. The main difference between the first preferred embodiment and this preferred embodiment is that a hole having a dual damascene structure 516 is formed in the dielectric layer 114 after a series of lithographic and etching processes are performed on the semiconductor wafer 110. The processes of etching the dual damascene structure 516 are well known in this art, so they are not described in detail there. Subsequently, the degas process, the barrier layer deposition process, the metal layer deposition process and the CMP process can be carried out as taught by the first preferred embodiment so as to complete the structure of the present invention.

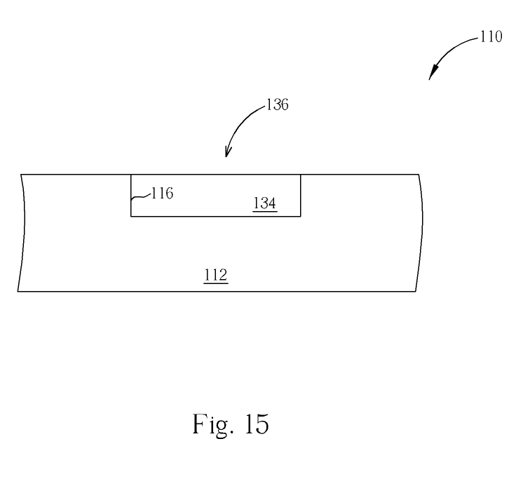

Furthermore, please refer to FIG. 15. FIG. 15 is a schematic diagram illustrating a method of manufacturing a shallow trench isolation structure in accordance with a sixth preferred embodiment of the present invention. The main differences between the first preferred embodiment and this preferred embodiment are the position of the hole structure 116 and the material filling the hole structure 116. The hole structure 116 is directly formed in the semiconductor substrate 112 of the semiconductor wafer 110 by an etching process, and one of the above-mentioned degas process is performed thereafter. Afterward, the hole structure 116 is filled with an insulating material 134, and next a CMP process is carried out to remove excess portions of the insulating material 134 from the semiconductor wafer 110 so as to complete a shallow trench isolation structure 136. The insulating material 134 can contain any materials having high dielectric constant, such as fluorinated silicate glass, undoped silicate glass, phosphosilicate glass or borophosposilicate glass.

In contrast to the prior art, the present invention includes an ultraviolet treatment in a degas process before depositing a material layer, so the present invention can degas the dielectric layer effectively. As a result, the subsequently formed material layer can cover the dielectric layer closely in the present invention, and the structure of the semiconductor device can be ensured.

Those skilled in the art will readily observe that numerous modifications and alterations of the device and method may be made while retaining the teachings of the invention.

1. A method of fabricating a semiconductor device, comprising:
providing a semiconductor substrate and a dielectric layer positioned on the semiconductor substrate;
etching the dielectric layer to form at least a hole structure in the dielectric layer;
performing an ultraviolet treatment and a heating process simultaneously and in-situly on the semiconductor substrate to make at least a gas escape from the dielectric layer;
forming a barrier layer on a sidewall and on a bottom of the hole structure; and
filling the hole structure with a conductive material.

2. The method of claim 1, wherein the gas escaping from the dielectric layer comprises water vapor.

3-5. (canceled)

6. The method of claim 1, wherein the dielectric layer comprises fluorinated silicate glass (FSG), undoped silicate glass (USG), phosphosilicate glass (PSG) or borophosposilicate glass (BPSG).

7. The method of claim 1, wherein the barrier layer comprises titanium (Ti) or titanium nitride (TiN).

8. The method of claim 1, wherein the conductive material comprises copper (Cu), aluminum (Al), tungsten (W) or alloys of the aforementioned metals.

9. The method of claim 1, wherein the hole structure comprises a plug hole structure.

10. The method of claim 1, wherein the hole structure comprises a dual damascene structure.

11-16. (canceled)

17. A method of fabricating a semiconductor device, comprising:
performing an etching process on a semiconductor substrate;
providing a degas chamber, the degas chamber having a carrier, a heating device and an ultraviolet lamp; and
transferring the semiconductor substrate into the degas chamber wherein an ultraviolet treatment and a heating process are simultaneously and in-situly performed by the ultraviolet lamp and the heating device so as to make a gas escape from the semiconductor substrate.

18. The method of claim 17 further comprising a step of transferring the semiconductor substrate into a physical vapor deposition chamber after the ultraviolet treatment, wherein a physical vapor deposition process is performed in the physical vapor deposition chamber to deposit a barrier layer on the semiconductor substrate.

19-24. (canceled)

25. A method of fabricating a semiconductor device, comprising:
providing a semiconductor substrate and a dielectric layer positioned on the semiconductor substrate;
etching the dielectric layer to form at least a hole structure in the dielectric layer;
performing an ultraviolet treatment and an X-ray treatment simultaneously and in-situly on the semiconductor substrate to make at least a gas escape from the dielectric layer;
forming a barrier layer on a sidewall and on a bottom of the hole structure; and
filling the hole structure with a conductive material.

26. The method of claim 25, wherein the gas escaping from the dielectric layer comprises water vapor.

27. The method of claim 25, wherein the dielectric layer comprises fluorinated silicate glass, undoped silicate glass, phosphosilicate glass or borophosposilicate glass.

28. The method of claim 25, wherein the barrier layer comprises titanium or titanium nitride.

29. The method of claim 25, wherein the conductive material comprises copper, aluminum, tungsten or alloys of the aforementioned metals.

30. The method of claim 25, wherein the hole structure comprises a plug hole structure.

31. The method of claim 25, wherein the hole structure comprises a dual damascene structure.

32. A method of fabricating a semiconductor device, comprising:
providing a semiconductor substrate and a dielectric layer positioned on the semiconductor substrate;
etching the dielectric layer to form at least a hole structure in the dielectric layer;
performing an ultraviolet treatment and a halogen lamp treatment simultaneously and in-situly on the semiconductor substrate to make at least a gas escape from the dielectric layer;
forming a barrier layer on a sidewall and on a bottom of the hole structure; and
filling the hole structure with a conductive material.

33. The method of claim 32, wherein the gas escaping from the dielectric layer comprises water vapor.

34. The method of claim 32, wherein the dielectric layer comprises fluorinated silicate glass, undoped silicate glass, phosphosilicate glass or borophosposilicate glass.

35. The method of claim 32, wherein the barrier layer comprises titanium or titanium nitride.

36. The method of claim 32, wherein the conductive material comprises copper, aluminum, tungsten or alloys of the aforementioned metals.

37. The method of claim 32, wherein the hole structure comprises a plug hole structure.

38. The method of claim 32, wherein the hole structure comprises a dual damascene structure.

39. A method of fabricating a semiconductor device, comprising:
performing an etching process on a semiconductor substrate;
providing a degas chamber, the degas chamber having a carrier, an X-ray device and an ultraviolet lamp; and
transferring the semiconductor substrate into the degas chamber wherein an ultraviolet treatment and an X-ray treatment are simultaneously and in-situly performed by the ultraviolet lamp and the X-ray device so as to make a gas escape from the semiconductor substrate.

40. The method of claim 39 further comprising a step of transferring the semiconductor substrate into a physical vapor deposition chamber after the ultraviolet treatment and the X-ray treatment, wherein a physical vapor deposition process is performed in the physical vapor deposition chamber to deposit a barrier layer on the semiconductor substrate.

41. A method of fabricating a semiconductor device, comprising:
performing an etching process on a semiconductor substrate;
providing a degas chamber, the degas chamber having a carrier, a halogen lamp and an ultraviolet lamp; and
transferring the semiconductor substrate into the degas chamber wherein an ultraviolet treatment and a halogen lamp treatment are simultaneously and in-situly performed by the ultraviolet lamp and the halogen lamp so as to make a gas escape from the semiconductor substrate.

42. The method of claim 41 further comprising a step of transferring the semiconductor substrate into a physical vapor deposition chamber after the ultraviolet treatment and the halogen lamp treatment, wherein a physical vapor deposition process is performed in the physical vapor deposition chamber to deposit a barrier layer on the semiconductor substrate.
